(19) United States
(12) Patent Application Publication
(10) Pub. No.: US 2026/0205138 A1
(43) Pub. Date: Jul. 16, 2026

(54) DELTA-SIGMA ANALOG-TO-DIGITAL CONVERTER AND BATTERY MONITOR DEVICE

(71) Applicant: DENSO CORPORATION, Kariya-city (JP)

(72) Inventor: Kazuo MATSUKAWA, Kariya-city (JP)

(21) Appl. No.: 19/561,955

(22) Filed: Mar. 10, 2026

Related U.S. Application Data
(63) Continuation of application No. PCT/JP2024/040160, filed on Nov. 12, 2024.

(30) Foreign Application Priority Data
Dec. 12, 2023 (JP) 2023-209332

(51) Int. Cl. H03M 3/00; G01R 31/382; G01R 31/396

(52) U.S. Cl. CPC H03M 3/464; G01R 31/382; G01R 31/396; H03M 3/378; H03M 3/404; H03M 3/422

(57) ABSTRACT

A delta-sigma A/D converter uses a differential operational amplifier. The first integrator has a differential configuration and includes a pair of feedback capacitors that are feedback-connected between the differential input terminals and the differential output terminals of the operational amplifier, and is provided with a switched capacitor that includes a chopping switch that can switch the polarity between the differential input terminals of the operational amplifier and the pair of feedback capacitors. The switch resets the potential of the differential input terminals of the operational amplifier at the timing when the feedback capacitor in the first integrator and the differential input terminals of the operational amplifier are disconnected by the chopping switch.

### CROSS REFERENCE TO RELATED APPLICATION

The present application is a continuation application of International Patent Application No. PCT/JP2024/040160 filed on Nov. 12, 2024, which designated the U.S. and claims the benefit of priority from Japanese Patent Application No. 2023-209332 filed on Dec. 12, 2023. The entire disclosures of all of the above applications are incorporated herein by reference.

### TECHNICAL FIELD

The present disclosure relates to a delta-sigma analog-to-digital (A/D) converter and a battery monitor device using the A/D converter.

### BACKGROUND

For example, a conceivable technique 1 teaches a technique for reducing A/D conversion errors caused by chopping by making chopping random.

### SUMMARY

According to an example, a delta-sigma A/D converter using a differential operational amplifier, the delta-sigma A/D converter may include: a pair of feedback capacitors that have a differential configuration and feedback-connect between differential input terminals and differential output terminals of the operational amplifier; and a first integrator functioning as a switched capacitor and having a chopping switch capable of switching polarity between the differential input terminals of the operational amplifier and the pair of feedback capacitors. The first integrator includes a switch that reset potentials of the differential input terminals of the operational amplifier when the feedback capacitor and the differential input terminals of the operational amplifier are disconnected by the chopping switch.

### BRIEF DESCRIPTION OF THE DRAWINGS

The above and other features of the present disclosure will become more apparent from the following detailed description made with reference to the accompanying drawings. In the drawing:

FIG. 1A is a diagram showing a part of the configuration of a delta-sigma A/D converter in a first embodiment;

FIG. 1B is a diagram showing the electrical configuration of the operational amplifier and its peripherals in the first embodiment;

FIG. 2 is a configuration diagram (part 1) of a delta-sigmaA/D converter in the first embodiment;

FIG. 3 is a configuration diagram (part 2) of a delta-sigmaA/D converter in the first embodiment;

FIG. 4 is an explanatory diagram of the first embodiment, showing the waveforms of each clock signal that controls the delta-sigma A/D converter;

FIG. 5 is a diagram illustrating the operation of the first integrator in the first embodiment;

FIG. 6 is a diagram (part 1) explaining the operation of the second integrator in the first embodiment and showing a feature to add the charges of Caa, Cas and Cs2 OF Φ1c to Cf2;

FIG. 7 is a diagram (part 2) explaining the operation of the second integrator in the first embodiment and showing a feature that the output of integrator 1 is input to Cas and Cs2 of Φ2c and sampling, and the output of integrator 1 is input to Caa of Φ2c and sampling (operation of upper half);

FIG. 8 is a diagram (part 3) explaining the operation of the second integrator in the first embodiment and showing a feature to add the charges of Cab Cas AND Cs2 of Φ1d to Cf2;

FIG. 9 is a diagram (part 4) explaining the operation of the second integrator in the first embodiment and showing a feature that the output of the integrator 1 is input to Cas and Cs2 of Φ2d and sampling and the output of the integrator 1 is input to Cab of Φ2d and sampling (operation of upper half);

FIG. 10 is a diagram showing a part of the configuration of a delta-sigma A/D converter in a comparative example;

FIG. 11 is a diagram explaining the operation of the first integrator in the comparative example;

FIG. 12 is an explanatory diagram of the deterioration of the integral nonlinearity error (i.e., INL) characteristics in a delta-sigma A/D converter of a comparative example;

FIG. 13 is an electrical configuration diagram of a first integrator in the first embodiment;

FIG. 14 is a diagram explaining the change in the charge accumulation state of the capacitor that constitutes the first integrator in the first embodiment;

FIG. 15 is an explanatory diagram of the second embodiment, showing the waveforms of the clock signals that control the delta-sigma A/D converter;

FIG. 16 is an explanatory diagram of the third embodiment, showing an electrical configuration block diagram of the battery monitor device;

FIGS. 17A and 17B are explanatory diagrams of the third embodiment, explaining the relationship between the signal band and the noise frequency band;

FIG. 18 is an explanatory diagram (part 1) of an example of a reset method in the fourth embodiment;

FIG. 19 is an explanatory diagram (part 2) of an example of a reset method in the fourth embodiment; and

FIG. 20 is an explanatory diagram (part 3) of an example of a reset method in the fourth embodiment.

### DETAILED DESCRIPTION

The technique described in the conceivable technique modulates the A/D conversion error spectrum by chopping, but does not eliminate the error. Furthermore, as the frequency of chopping decreases, flicker noise does not reach the high frequency range and affects the low frequency range as random noise. Furthermore, a separate circuit for generating pseudo-random numbers is required, which increases the area and current consumption.

The present embodiments have been made in consideration of the above circumstances, and its purpose is to provide a delta-sigma A/D converter that can reduce A/D conversion errors caused by chopping, and a battery monitor device that uses the A/D converter.

According to one aspect of the present embodiments, a delta-sigma A/D converter using a differential operational amplifier includes a pair of feedback capacitors that are feedback-connected between the differential input terminals and the differential output terminals of the differential operational amplifier, and a first integrator that uses switched capacitors and includes a chopping switch that can switch the polarity between the differential input terminals of the operational amplifier and the pair of feedback capacitors. Also, a switch is provided that resets the potential of the differential input terminals of the operational amplifier at the timing when the feedback capacitor in the first integrator and the differential input terminals of the operational amplifier are disconnected by the chopping switch.

According to the delta-sigma A/D converter of one aspect of the present embodiments, the switch resets the potential of the differential input terminals of the operational amplifier at the timing when the feedback capacitor and the differential input terminals of the operational amplifier are disconnected by the chopping switch. Therefore, the A/D conversion error caused by chopping occurring at the differential input terminals of the operational amplifier can be eliminated, and the A/D conversion error caused by chopping can be reduced.

Hereinafter, several embodiments of a data generation device and a battery monitor device will be described with reference to the drawings. In the embodiments described later, the same or similar reference numerals as those in the embodiments described previously will be used to designate the components, and the description thereof will be omitted.

### First Embodiment

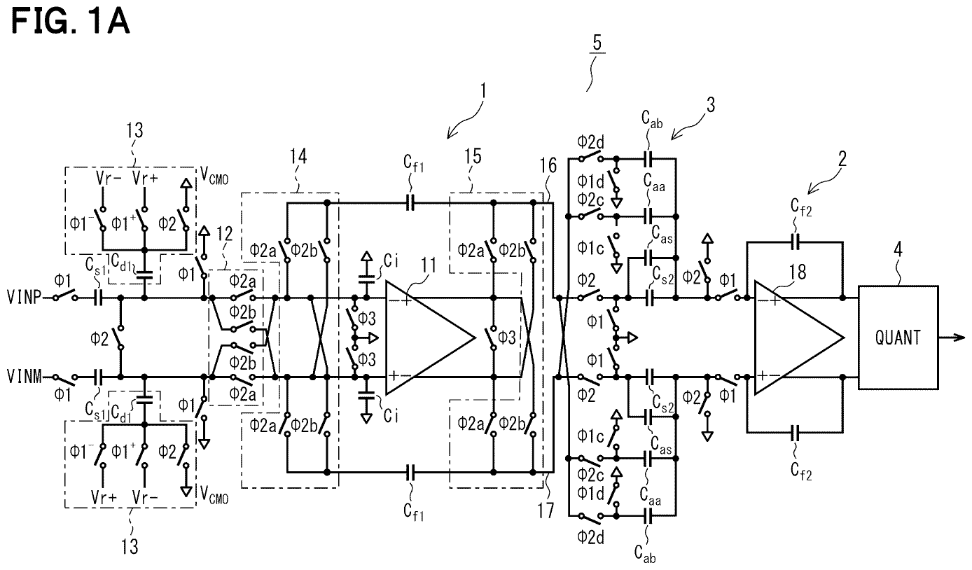

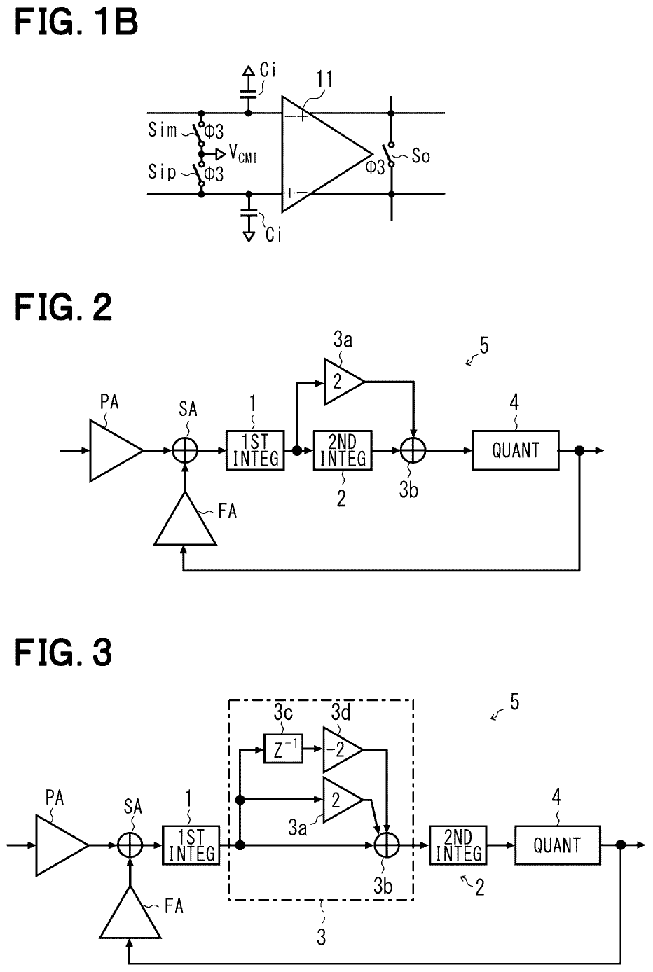

FIG. 1A shows a part of a CIFF type second-order delta-sigma A/D converter 5 according to this embodiment. In addition, in FIG. 1B, the switches D3 around the input and output of the operational amplifier 11 shown in FIG. 1A are distinguishably labeled as switches Sip, Sim, and So.

FIG. 1A illustrates an extracted portion of the block configuration of the delta-sigma A/D converter 5 shown in FIG. 2. The delta-sigma A/D converter 5 shown in FIG. 2 has a first integrator 1 and a second integrator 2 connected in series. The adder 3b shown in FIG. 2 adds a value obtained by doubling the output of the first integrator 1 using gain 3a and the output of the second integrator 2, and outputs the result to the quantizer 4. The output of the quantizer 4 is fed back via a feedback D/A converter 13 so as to be subtracted from the input signal.

The configuration shown in FIG. 2 includes a gain 3a for doubling (i.e., ×2), an adder 3b, a delay device 3c, and a gain 3d for minus doubling (i.e., ×(−2)), but the configuration in FIG. 2 is equivalent to a configuration in which the pseudo-addition circuit 3 is placed on the input side of the second integrator 2 as shown in FIG. 3. The pseudo-addition circuit 3 adds the output of the first integrator 1, a value obtained by doubling the output of the first integrator 1 using a gain 3a, and a value obtained by minus doubling the output of the first integrator 1 using the gain 3d via a delay device 3c.

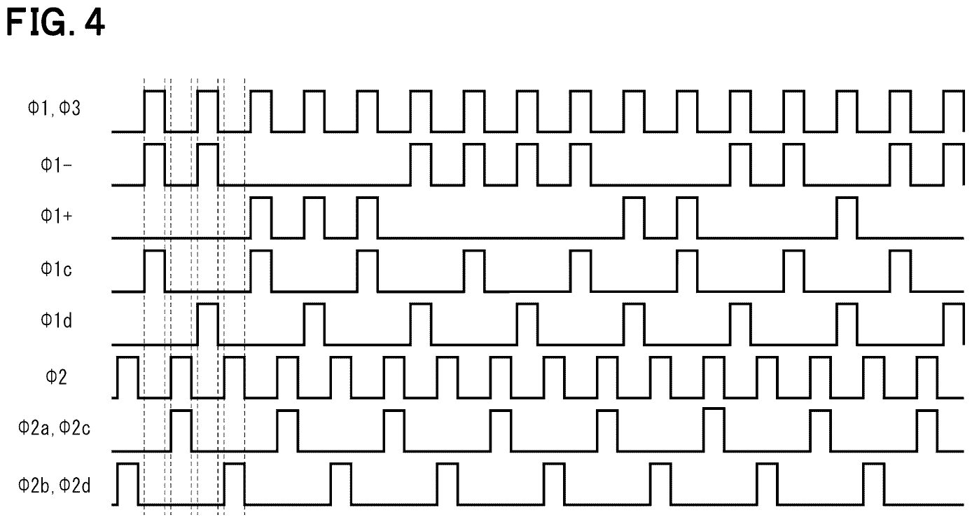

The delta-sigma A/D converter 5, a part of which is shown in FIG. 1A, is implemented as a differential circuit based on the block configuration shown in FIG. 3. The delta-sigma A/D converter 5 has a switched capacitor configuration that performs chopping on the input side of the first integrator 1 and charges and discharges each capacitor (reference numerals omitted). The delta-sigmaA/D converter 5 operates with eleven types of clock signals shown in FIG. 4. It should be noted that, for ease of understanding, in the following description, the symbols for the switches Φ1, Φ1c, Φ1d, Φ2, Φ2a, Φ2b, and Φ3 shown in FIG. 1 may also be used to explain the clock phases (i.e., clock signals).

Φ1 denotes a master clock signal.

Φ1+ denotes an output if the output of the quantizer 4 is L.

Φ1− denotes an output if the output of the quantizer 4 is H.

Φ1c denotes an odd-numbered clock of Φ1.

Φ1d denotes an even-numbered clock of Φ1.

Φ2 denotes an inversion phase clock signal of Φ1.

Φ2a and Φ2c denote odd-numbered clocks of Φ2.

Φ2b and Φ2d denote even-numbered clocks of Φ2.

Φ3 denotes a reset signal (which is synchronized with the master clock).

The odd and even numbers are relative numbers when the left end of Φ1 of the master clock shown in FIG. 4 is set to “1”, for example. Also, to make the explanation easier to understand, it should be noted that the switches described below that are turned on by the above clock signals may be described with the clock type attached as a symbol.

As shown in FIG. 1, the first integrator 1 includes an operational amplifier 11 having a fully differential configuration. Between the nodes of the positive input voltage VINP and the negative input voltage VINM and the differential input terminal of the operational amplifier 11, a series circuit of a switch Φ1, a capacitor Cs1 which is a sampling capacitance element, and a chopping switch 12 is connected. The chopping switch 12 includes two switches Φ2a and two switches Φ2b. The two switches Φ2a connect in a straight line between the node of the positive input voltage VINP and the negative input terminal of the operational amplifier 11, and between the node of the negative input voltage VINM and the positive input terminal of the operational amplifier 11, respectively. The two switches Φ2b are connected so as to cross between the nodes of the input voltages VINP and VINM and the differential input terminal of the operational amplifier 11.

A common connection point between the capacitor Cs1 and the chopping switch 12 is connected to one end of a capacitor Cd1 constituting the D/A converter 13 and one end of a switch Φ1. The other end of capacitor Cd1 is commonly connected to one end of switches Φ1−, Φ1+, and Φ2 that constitute the D/A converter 13, and the other ends of switches Φ1−, Φ1+, and Φ2 and switch Φ1 are connected to reference voltages Vr−, Vr+, and a reference potential VCMO, respectively. The reference potential VCMO is an output common mode potential, and the magnitude relationship between these voltages is set to an expression of “Vr−<VCMO<Vr+”.

The chopping switch 12 is capable of switching the polarity between the nodes of the input voltages VINP and VINM and the differential input terminal of the operational amplifier 11. The chopping switch 14 also switches the polarity between the differential input terminal of the input-side operational amplifier 11 and the pair of feedback capacitors Cf1. An input parasitic capacitance Ci exists between a common connection point of the switches Φ2a constituting the chopping switches 12 and 14 and the node of the reference potential VCMO and between the common connection point between the differential input terminals of the operational amplifier 11 and the node of the reference potential VCMO, respectively. In order to suppress the influence of A/D conversion errors due to this parasitic capacitance Ci, as shown in FIG. 1B, the switches Sim and Sip (Φ3) are connected between the negative input terminal of the operational amplifier 11 and the node of the input common potential VCMI, and between the positive input terminal and the node of the input common potential VCMI, respectively.

As shown in FIG. 1A, a series circuit of a chopping switch 14, a feedback capacitor Cf1, and a chopping switch 15 is connected between the input and output sides of an operational amplifier 11. Similar to the chopping switch 12, each of these chopping switches 14 and 15 includes two switches Φ2a and two switches Φ2b. The switch Φ2a is connected straight between the negative input terminal and the positive output terminal, and between the positive input terminal and the negative output terminal, and the switch Φ2b is connected crosswise so that the polarity of the input side and the output side is reversed. The chopping switch 15 corresponds to an output side chopping switch. Either the positive or negative output signal of the first integrator 1 corresponds to a first output signal, and the other corresponds to a second output signal. A switch So (Φ3) is connected between the differential output terminals of the operational amplifier 11, and is provided to suppress the influence of the parasitic capacitance generated around the operational amplifier 11.

The second integrator 2 is configured in the subsequent stage of the first integrator 1, with a pseudo-addition circuit 3 disposed on the input side. Between the output line 16 of the first integrator 1 and the negative input terminal of the fully differential operational amplifier 18 that constitutes the second integrator 2, a switch Φ2 that constitutes the one polarity side of the pseudo-addition circuit 3, a parallel circuit of the capacitors Cs2 and Cas, and a series circuit of switches Φ1 are connected. The configuration between the output line 17 of the first integrator 1 and the positive input terminal of the operational amplifier 18 is also similar to the above feature.

A series circuit of a switch Φ2c and a capacitor Caa, and a series circuit of a switch Φ2d and a capacitor Cab are connected between the output line 17 and a common connection point of the capacitors Cs2 and Cas and the switch Φ1, respectively. The switches Φ1c and Φ1d are connected between the common connection point of each series circuit and a reference voltage, respectively. The configuration on the side connected to the output line 16 is similar to the above feature. A switch Φ2 is connected between a common connection point of the capacitors Cs2 and Cas and the switch Φ1 and a reference voltage. The capacitances of the capacitors Cas, Caa, and Cab are set to be equal. The capacitors Cas, Caa and Cab correspond to capacitance elements for addition, odd-number subtraction and even-number operation, respectively.

A feedback capacitor Cf2 is connected between the differential input terminal and differential output terminal of the operational amplifier 18 that constitutes the second integrator 2, and the differential output terminal is connected to the input terminal of the quantizer 4. The pseudo-addition circuit 3 performs addition using the configuration of the second integrator 2 as follows. The delta-sigma A/D converter 5 is configured as described above.

Next, the operation of the present embodiment will be described. First, the operation of the first integrator 1 will be described. In this embodiment, an operation will be described in which the input side of the operational amplifier 11 is chopped every time by the chopping switches 12 and 14. In the following, in order to make the operation easier to understand, illustrations of the individual switches are omitted where appropriate, and the switches that are turned on in accordance with the respective clocks are indicated by solid lines. In this embodiment, the clock is generated to cyclically turn on the switches in the order of Φ1, Φ2a, Φ1, Φ2b, and so on, thereby repeatedly executing the four phases.

### (v1: Sampling Phase)

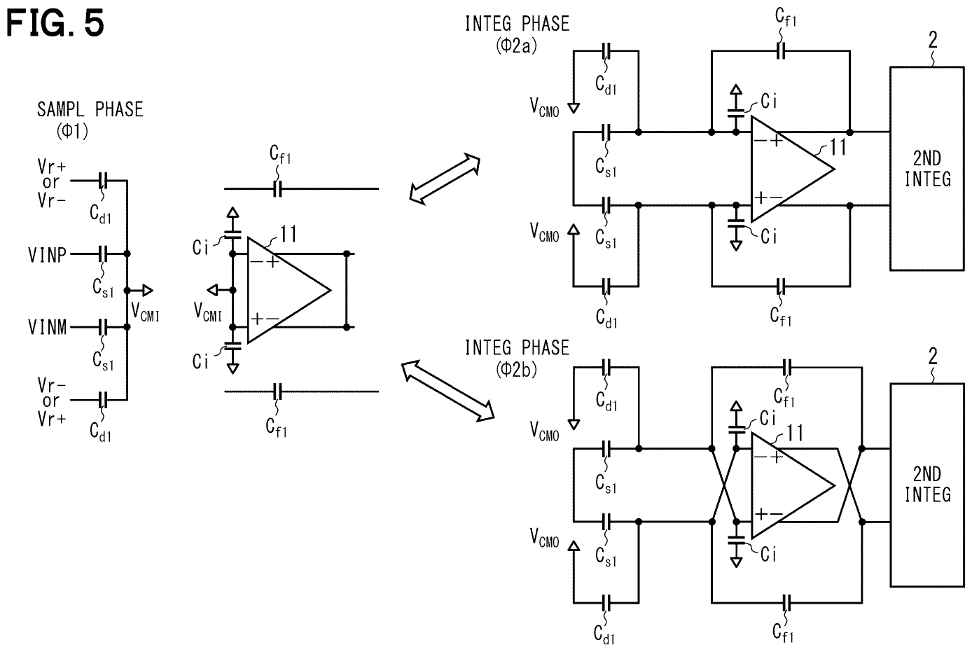

In the sampling phase shown on the left side of FIG. 5, a sampling process is performed in which the capacitor Cs1 is charged by the input voltages VINP and VINM. Simultaneously with the on timing of the switch Φ1, the switches Φ1− and Φ1+ are selectively turned on and off depending on the output of the quantizer 4, and the capacitor Cd1 of the D/A converter 13 is charged and discharged. At the same time, the feedback capacitor Cf1 and the input terminal of the operational amplifier 11 are disconnected by the chopping switch 14. Furthermore, by turning on the switches Sim and Sip, the differential input terminal of the operational amplifier 11 is short-circuited and the differential input terminal is connected to the input common node, and the potentials of both input terminals are reset to the input common potential VCMI.

### (Φ2a: Integration Phase a)

Next, in integration phase a shown in the upper right of FIG. 5, the feedback capacitor Cf1 and the differential input terminal of operational amplifier 11 are connected in a straight line by the chopping switch 14, and the charges of capacitors Cs1 and Cd1 are integrated in the feedback capacitor Cf1.

### (Φ1: Sampling Phase)

Next, the process returns to the sampling phase shown on the left side of FIG. 5. At this time, as in the above, the capacitor Cs1 is charged with the input voltages VINP and VINM and the sampling is performed. Simultaneously with the on timing of the switch Φ1, the switches Φ1− and Φ1+ are selectively turned on and off depending on the output of the quantizer 4, and the capacitor Cd1 of the D/A converter 13 is charged and discharged. Furthermore, the feedback capacitor Cf1 and the input terminal of the operational amplifier 11 are disconnected by the chopping switch 14. Furthermore, by turning on the switches Sim and Sip, the differential input terminal of the operational amplifier 11 is short-circuited, and the potentials of both input terminals are stabilized at the input common potential VCMI, so that both potentials of the differential input terminals are reset.

The switches Sim and Sip (Φ3) shown in FIG. 1B are configured to set the differential input terminals of the operational amplifier 11 to a predetermined input common potential VCMI, respectively, so that the potentials of the positive input terminal and the negative input terminal can be stably determined when resetting. Furthermore, the switch So is configured to connect the differential output terminals of the operational amplifier 11 to each other to set the differential output terminals at the same potential, so that the differential output terminals can be reset to stable potentials.

### (Φ2b: Integration Phase b)

Next, the process moves to the integration phase b shown in the lower right of FIG. 5. At this time, the polarity of the input/output terminals of the operational amplifier 11 is switched to cross-connection by the chopping switches 12, 14, and 15, and the charges of the capacitors Cs1 and Cd1 are integrated in the feedback capacitor Cf1.

In this way, the four phases are repeated periodically. The first integrator 1 resets the voltage of the input terminal of the operational amplifier 11 to the input common potential VCMI during the sampling phase Φ1 every time the integration phase a or b is completed. This allows the first integrator 1 to perform the integration without accumulating errors as much as possible.

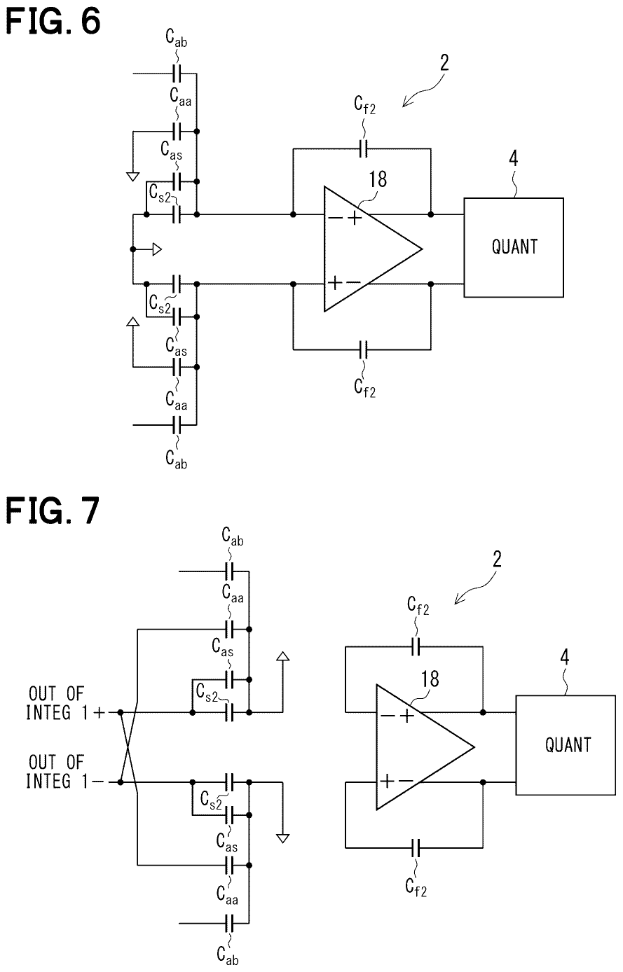

Next, the operation of the pseudo-addition circuit 3 and the second integrator 2 will be described. In the operation of the second integrator 2 shown in FIGS. 6 to 9, the clocks are generated cyclically in the order of Φ1c, Φ2c, Φ1d, Φ2d, Φ1c, and so on, and four phases are repeatedly executed. Further, the explanation involving positive and negative polarities will be given with respect to one side of the differential configuration, that is, the upper side in the drawing.

### <Φ1c: First Phase>

In the first phase shown in FIG. 6, the charges on capacitors Caa, Cas and Cs2 are added to the feedback capacitor Cf2.

### <Φ2c: Second Phase>

In the second phase shown in FIG. 7, the capacitors Cas and Cs2 are charged with the positive output of the first integrator 1 and sampled, and the capacitor Caa is charged with the negative output of the first integrator 1 and sampled.

### <Φ1d: Third Phase>

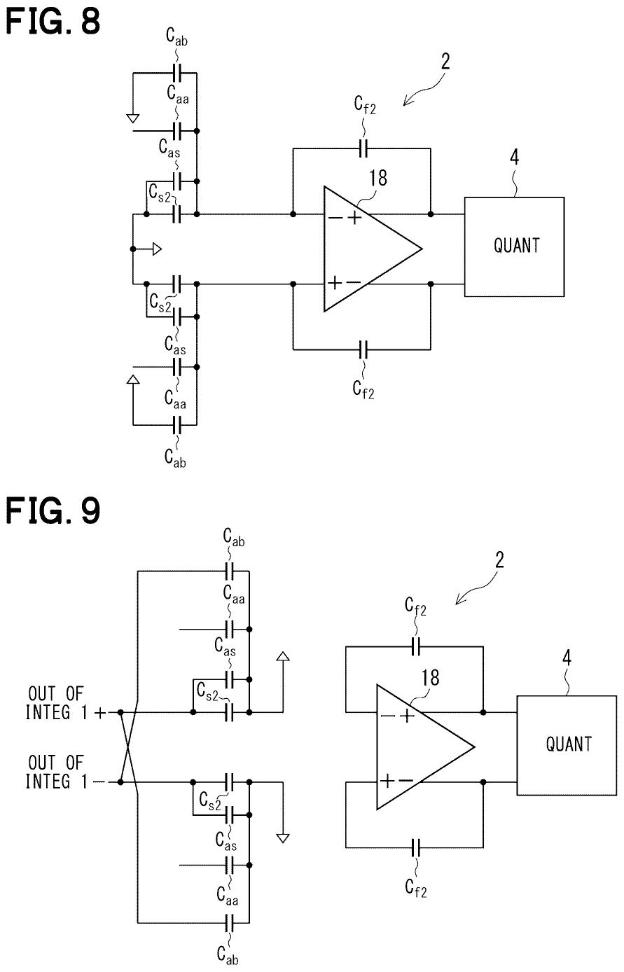

In the third phase shown in FIG. 8, the charges on capacitors Cab, Cas and Cs2 are added to the feedback capacitor Cf2.

### <Φ2d: Fourth Phase>

In the fourth phase shown in FIG. 9, the capacitors Cas and Cs2 are charged with the positive output of the first integrator 1 and sampled, and the capacitor Cab is charged with the negative output of the first integrator 1 and sampled.

As a result of repeating the above operation, the output of each addition result in the first and third phases in a time series is added with twice the value of the input at that time, and at the timing of the next addition, the double value added previously is subtracted. In this manner, the input voltages are sequentially cumulatively added.

### Comparative Example

The inventor originally developed a delta-sigma A/D converter 5 that performs the A/D conversion processing without taking the parasitic capacitance Ci into consideration, but discovered that an A/D conversion error occurs. As a result of investigating the factor of this occurrence, the inventor has found that a parasitic capacitance Ci is generated at the differential input terminals of the operational amplifier 11, and that charge is accumulated in this parasitic capacitance Ci. It was discovered that when the positive and negative terminals of the input and output terminals of the operational amplifier 11 are reversely connected due to chopping, this affects the integration value of the first integrator 1 in the first stage as an error charge.

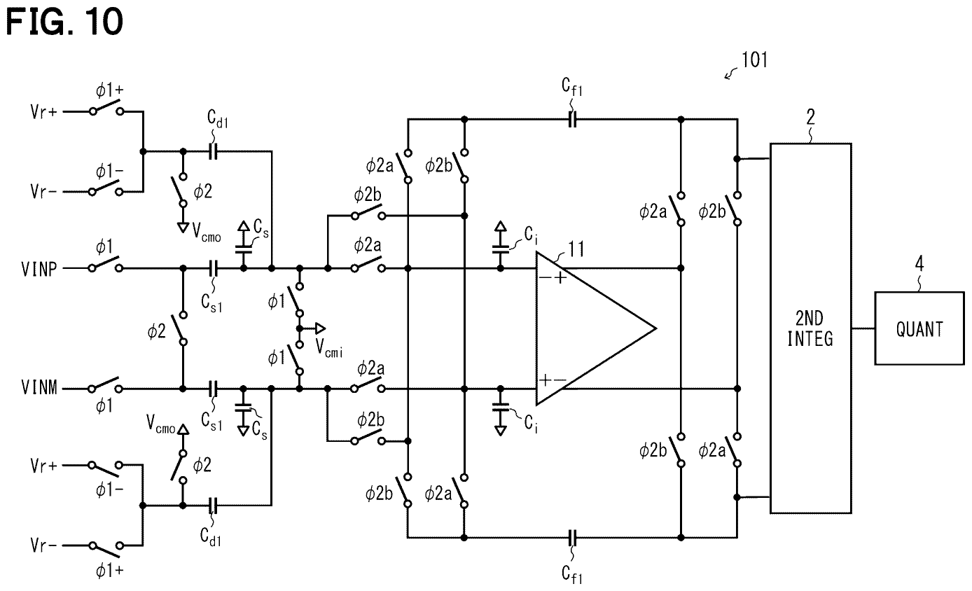

FIG. 10 shows the configuration of a first integrator 101 that replaces the first integrator 1 as a comparative example. The first integrator 101 shows a configuration example in which the influence of the parasitic capacitance Ci occurring at the input of the operational amplifier 11 is not taken into consideration. Compared to the first integrator 1 of this embodiment, the first integrator 101 does not have a switch CD3 between the differential input terminals and between the differential output terminals of the operational amplifier 11.

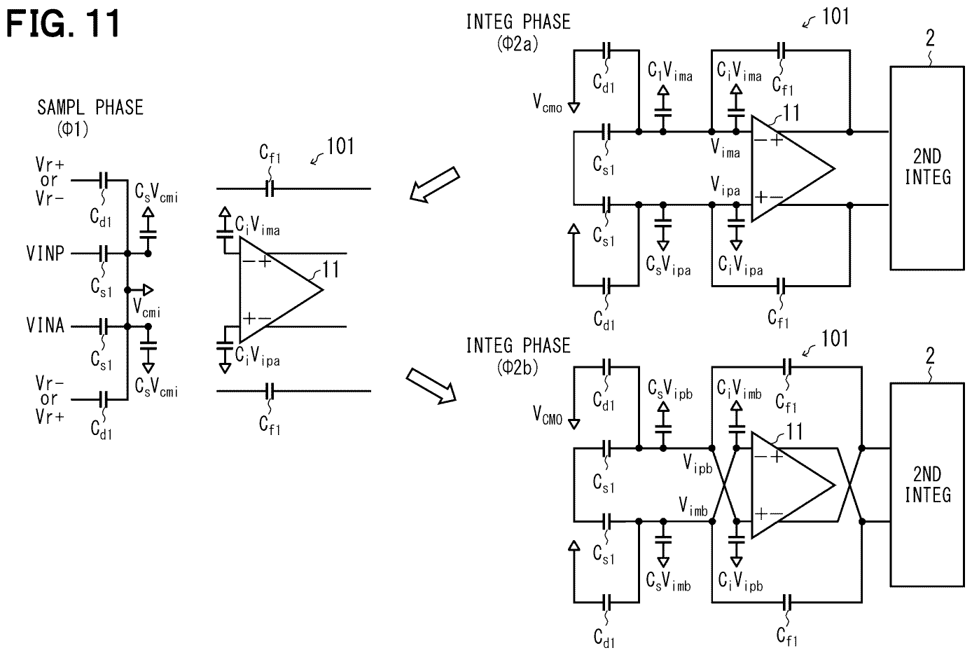

Then, as shown in the left diagram of FIG. 11, the operation of the first integrator 101 is such that the charges CiVima and CiVipa corresponding to the potentials Vima and Vipa occurring at the differential input terminals of the operational amplifier 11 during the integration phase a remain in the parasitic capacitance Ci of the input of the operational amplifier 11. Therefore, the influence of the error is accumulated in the integration phase b.

This operation can be expressed mathematically as follows. Consider the output error of the first integrator 101 based on the error charge when the phase shifts from Φ2a to Φ2b through Φ1. When considering the expression, for simplicity, the influence of the sampling capacitor Cs1 and the capacitor Cd1 of the D/A converter 13 is omitted and the initial charge of the feedback capacitor Cf1 is considered to be zero.

As shown in FIG. 10, when the switch Φ3 is not provided and no reset is performed, and the phases from Φ2a to Φ2b through Φ1 are switched, the values of the positive input voltage Vintp and the negative input voltage Vintm of the operational amplifier 11 can be derived as shown in the following expression (1). This value is determined based on changes in the charge accumulation state of the parasitic capacitance Ci, the capacitor Cs, and the feedback capacitor Cf1.

$$\begin{matrix}( Expression 1 ) & \\ {V}_{intp} = \frac{{C}_{i} ( {V}_{i p b} - {V}_{i p a} ) + {C}_{s} ( {V}_{i p b} - {V}_{c m i} )}{{C}_{f 1}} & ( 1 )\end{matrix}$$

$${V}_{intm} = \frac{{C}_{i} ( {V}_{i m b} - {V}_{i m a} ) + {C}_{s} ( {V}_{i m b} - {V}_{c m i} )}{{C}_{f 1}}$$

When the term of “Vintp−Vintm” is derived from this expression (1), it can be derived as in expression (2).

$$\begin{matrix}( Expression 2 ) & \\ \begin{matrix}{V}_{int} = {V}_{intp} - {V}_{intm} \\ = \frac{{C}_{i} ( {V}_{i p b} - {V}_{i p a} ) + {C}_{s} ( {V}_{i p b} - {V}_{c m i} )}{{C}_{f 1}} \\ - \frac{{C}_{i} ( {V}_{i m b} - {V}_{i m a} ) + {C}_{s} ( {V}_{i m b} - {V}_{c m i} )}{{C}_{f 1}} \\ = \frac{{C}_{i} ( {V}_{i p b} - {V}_{i m b} - {V}_{i p a} + {V}_{i m a} ) + {C}_{s} ( {V}_{i p b} - {V}_{i m b} )}{{C}_{f 1}}\end{matrix} & ( 2 )\end{matrix}$$

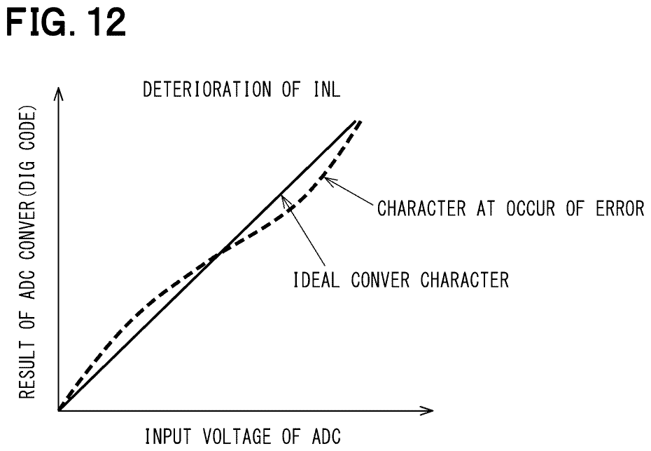

In this way, the voltage of “−Vipa+Vima” at the time of phase Φ2a remains, and the accumulation of the error charge of “Ci/Cf1×(−Vipa+Vima)” based on this voltage is repeated many times, so that an accumulation error is generated. When an error occurs, as shown in FIG. 12, the input level dependency of the delta-sigma A/D converter 5 becomes large, and the integral nonlinearity error (INL) becomes large.

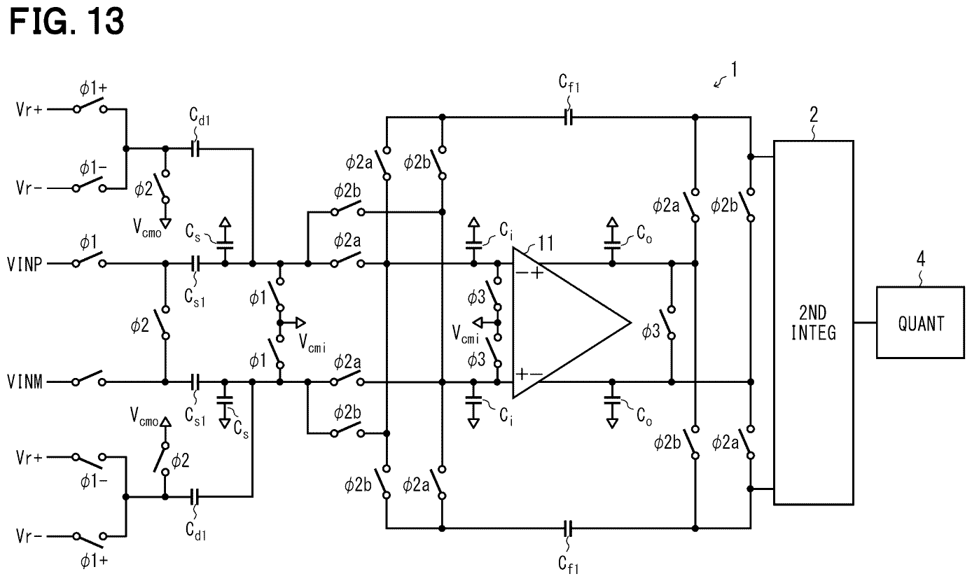

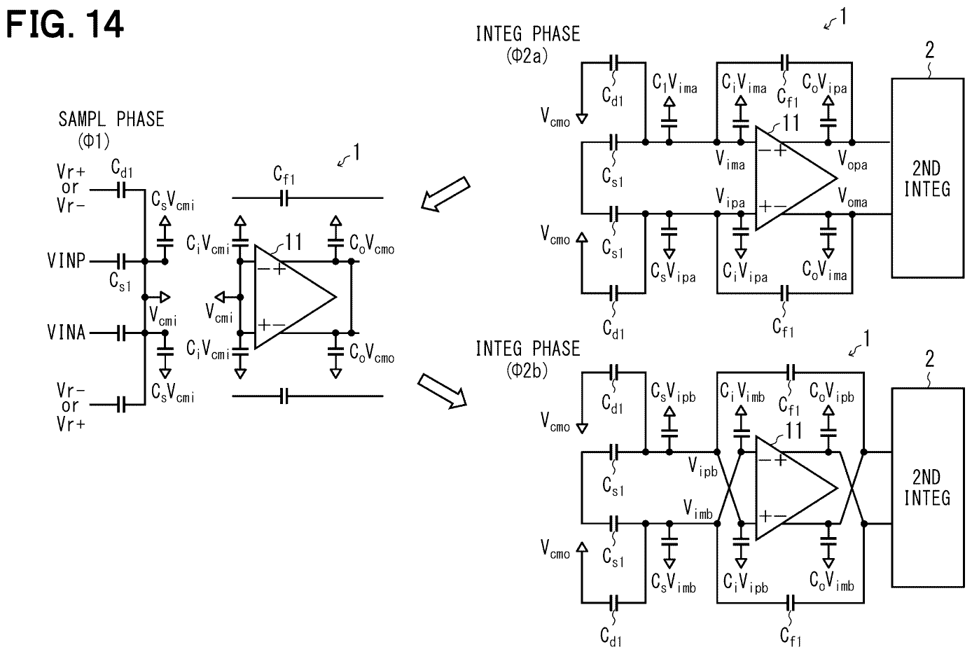

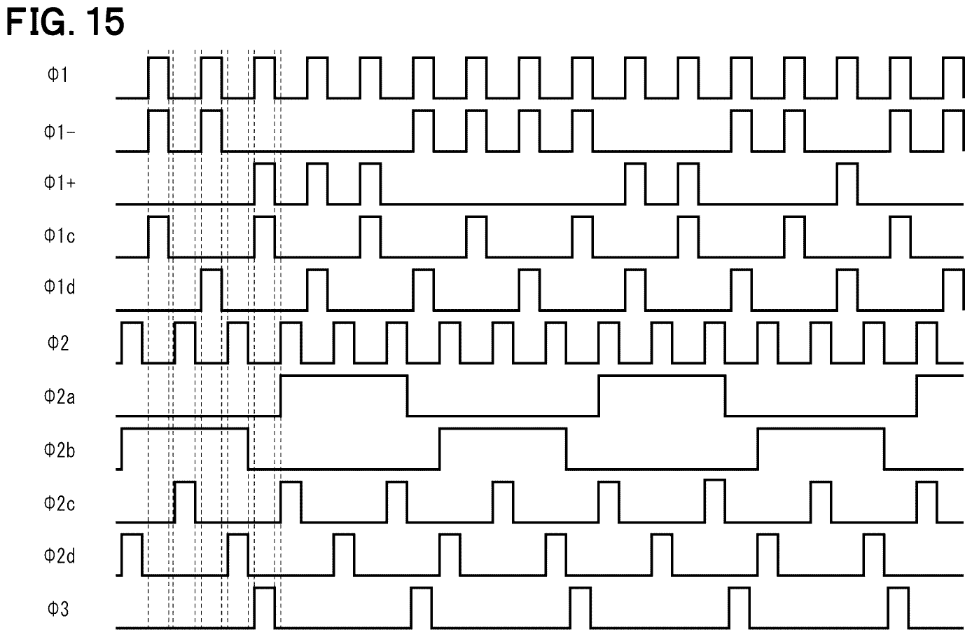

FIG. 13 also shows the first integrator 1 when the parasitic capacitances Ci and Co at the input and output of the operational amplifier 11 are taken into consideration. According to the delta-sigma A/D converter 5 of this embodiment, the differential input terminals and differential output terminals of the operational amplifier 11 can be reset in the sampling phase using the switch Φ3 newly provided at the input and output of the operational amplifier 11. FIG. 14 shows the change in the charge accumulation state of the parasitic capacitance Ci, the capacitor Cs, and the feedback capacitor Cf1 when the phase changes from Φ2a to Φ2b through Φ1.

This operation can be expressed mathematically as follows. Consider the output error of the first integrator 1 based on the error charge when the phase shifts from Φ2a to Φ2b through Φ1.

When the reset process is performed as shown in FIG. 14, the values of the positive input voltage Vintp and the negative input voltage Vintm of the operational amplifier 11 based on the changes in the charge accumulation state of the parasitic capacitance Ci, the capacitor Cs, and the feedback capacitor Cf1 when the phase is changed from Φ2a to Φ2b through Φ1 can be derived as shown in the following expression (3).

$$\begin{matrix}( Expression 3 ) & \\ {V}_{intp} = \frac{{C}_{i} ( {V}_{i p b} - {V}_{cmi} ) + {C}_{s} ( {V}_{i p b} - {V}_{c m i} )}{{C}_{f 1}} & ( 3 )\end{matrix}$$

$${V}_{intm} = \frac{{C}_{i} ( {V}_{i m b} - {V}_{cmi} ) + {C}_{s} ( {V}_{i m b} - {V}_{c m i} )}{{C}_{f 1}}$$

When the term of “Vintp−Vintm” is derived from expression (3), it can be derived as in expression (4). In expression (4), the element of voltage Vcmi is canceled out, and the voltage of “−Vipa+Vima” during the phase Φ2a described above does not remain. This makes it possible to reduce A/D conversion errors caused by the chopping.

$$\begin{matrix}( Expression 4 ) & \\ \begin{matrix}{V}_{int\_err} = {V}_{intp\_err} - {V}_{intm\_err} \\ = \frac{{C}_{i} ( {V}_{i p b} - {V}_{cmi} ) + {C}_{s} ( {V}_{i p b} - {V}_{c m i} )}{{C}_{f 1}} \\ - \frac{{C}_{i} ( {V}_{i m b} - {V}_{cmi} ) + {C}_{s} ( {V}_{i m b} - {V}_{c m i} )}{{C}_{f 1}} \\ = \frac{{C}_{i} ( {V}_{i p b} - {V}_{i m b} ) + {C}_{s} ( {V}_{i p b} - {V}_{i m b} )}{{C}_{f 1}}\end{matrix} & ( 4 )\end{matrix}$$

### Overview of the Present Embodiment

According to this embodiment, at the timing when the feedback capacitor Cf1 and the input terminal of the operational amplifier 11 are disconnected by the chopping switch 14, the switch Φ3 resets the potential of the input terminal of the operational amplifier 11 in the sampling phase. In this embodiment, the resetting is performed by short-circuiting the positive input terminal and the negative input terminal of the operational amplifier 11 and stabilizing the voltage to the input common potential VCMI. Therefore, the A/D conversion error caused by the chopping occurring at each differential input terminal of the operational amplifier 11 can be eliminated, and the A/D conversion error caused by the chopping can be reduced.

Furthermore, according to this embodiment, the switches Sim and Sip (Φ3) are configured to set the differential input terminals of the operational amplifier 11 to predetermined input common potentials VCMI, respectively, so that the potentials of the positive input terminal and the negative input terminal can be stably determined when resetting. Furthermore, the switch So is configured to connect the differential output terminals of the operational amplifier 11 together to set the differential output terminals at the same potential, so that the differential output terminals can be reset to stable potentials without separately driving the reference potential VCMO, and it is possible to constitute the switch So without requiring a separate drive circuit.

### Second Embodiment

The second embodiment will be described with reference to FIG. 15. In the second embodiment, an operation will be described in which the input side of the operational amplifier 11 is chopped by the chopping switches 12 and 14 every three clocks of Φ1. As shown in FIG. 15, clocks are generated in the order of Φ2a (that is equal to three clocks of Φ1), Φ3, Φ2b (that is equal to three clocks of Φ1), Φ3, and so on. Even in such a case, the potential of the input terminal of the operational amplifier 11 can be reset at the timing of the clock signal Φ3, and the same effects as those of the above-described embodiment can be obtained.

### Third Embodiment

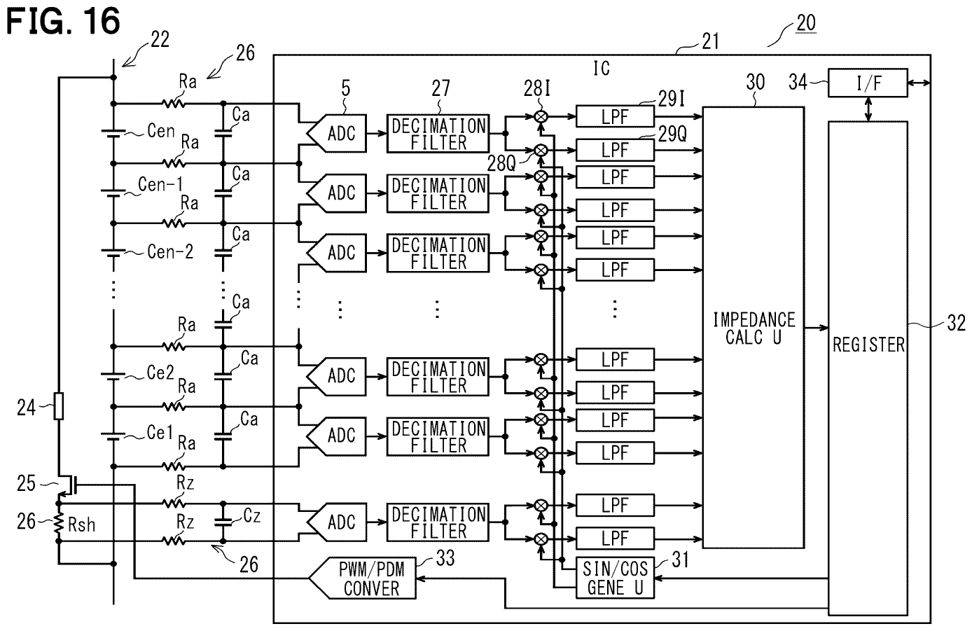

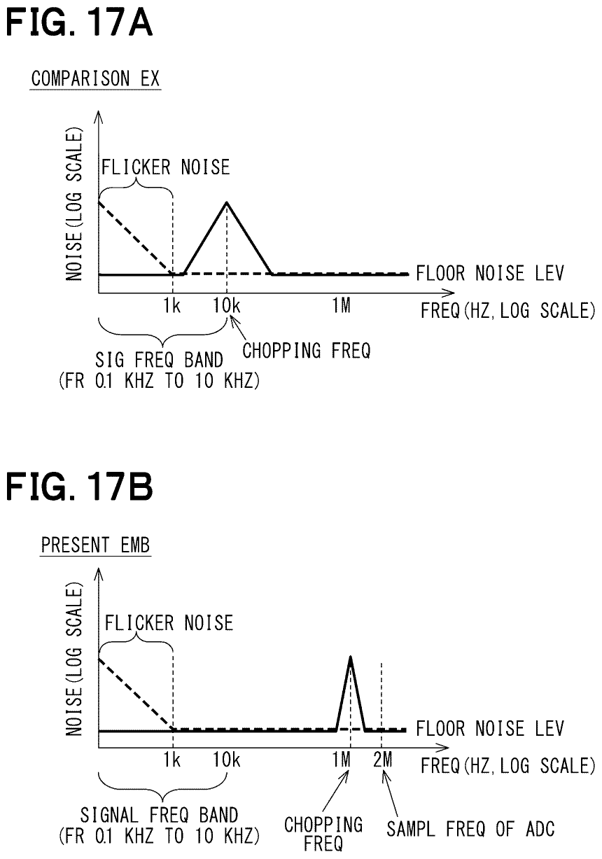

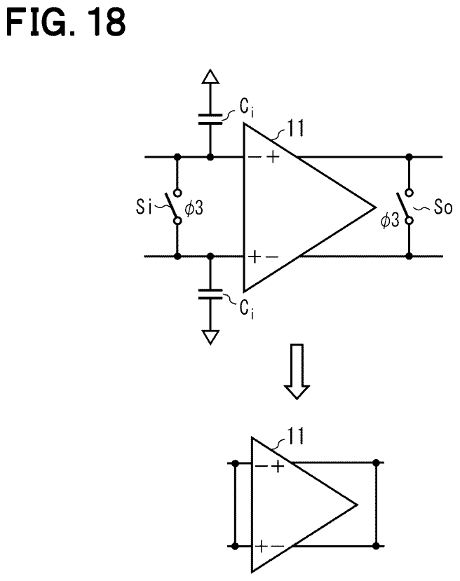

The third embodiment will be described with reference to FIGS. 16 and 17. FIG. 16 shows a configuration in which the delta-sigma A/D converter 5 of the first embodiment is applied to a battery monitor IC 21 having a battery impedance measurement function of a lock-in amplifier system.

The battery monitor device 20 includes a battery monitor IC 21 and an external RC filter 26. The battery monitor IC 21 is configured using an integrated circuit, and measures the impedance of each of n (for example, 24) pieces of unit cells Ce 1 to Cen that constitute the battery pack 22. A series circuit of a limitation resistor 24, an N-channel MOSFET 25, and a shunt resistor Rsh is connected in parallel to the battery pack 22. The limitation resistor 24 controls the on/off operation of the MOSFET 25 to limit the magnitude of the intermittent current that flows therethrough.

An RC filter 26, which is a low-pass type filter including a resistor Ra and a capacitor Ca, is connected to each of the unit cells Ce1 to Cen, which are secondary batteries. Both ends of the capacitor Ca that constitutes the RC filter 26 are connected to the input terminals of the delta-sigma ND converter 5 of the battery monitor IC 21. Both ends of the shunt resistor Rsh are connected to the input terminals of another delta-sigma ND converter 5 via an RC filter 26 including a resistor Rz and a capacitor Cz.

The battery monitor IC 21 includes a plurality of sets of a delta-sigma ND converter 5, a decimation filter 27, multipliers 281 and 28Q, and LPFs 291 and 29Q, and the number of sets is equal to the number of unit cells Ce1, Ce2, . . . Cen plus one for current measurement. In addition, the battery monitor IC 21 includes a SIN/COS generation unit 31, a PWM/PDM modulator 33, an impedance calculation unit 30, and a register 32. The impedance calculation unit 30 includes a digital control circuit and a counter.

The register 32 is connected to an interface 34 for communicating with an external device. The register 32 is written to by an external higher level device or the like via an interface 34, whereby the frequency setting of the SIN/COS generation unit 31 and the modulation method in the PWM/PDM modulator 33 are set. When the register 32 receives a measurement start command via the interface 34, the SIN/COS generation unit 31 starts operating and the PWM/PDM modulator 33 also starts operating.

The PWM/PDM modulator 33 outputs a PWM (Pulse Width Modulation) signal or a PDM (Pulse Density Modulation) signal based on a modulation method set in the register 32 via an interface 34 from an external higher-level control device or the like. A PWM/PDM modulator 33 is connected to the gate of the FET 25, and the above described PWM signal or PDM signal is given to it. When the FET 25 is turned on, the delta-sigma A/D converter 5 detects a terminal voltage corresponding to the excitation current flowing from the battery pack 22 through the limitation resistor 24 to the shunt resistor Rsh.

The delta-sigma A/D converter 5 measures the terminal voltages of the unit cells Ce1, Ce2, . . . Cen and the terminal voltage of the shunt resistor Rsh and performs the A/D conversion. The output data of the delta-sigma A/D converter 5 is input to a decimation filter 27. The decimation filter 27 uses a CIC (Cascaded Integrator-Comb) filter, which reduces the sampling frequency and converts the signal into a multi-bit digital value.

The output of the decimation filter 27 is branched into two pieces and input to multipliers 281 and 28Q. The multipliers 281 and 28Q receive the sine and cosine signals generated by the sine/cosine generation unit 31 and perform the orthogonal conversion. The outputs of the multipliers 281 and 28Q are input to LPFs 291 and 29Q, respectively. The LPFs 291 and 29Q cut off high frequencies to obtain desired DC data, and output the real and imaginary parts of the DC data to the impedance calculation unit 30, respectively.

The impedance calculation unit 30 receives each input and outputs the calculated impedances of the unit cells Ce1, Ce2, . . . , Cen to the register 32. The impedance value data stored in the register 32 is transmitted to an external higher-level control device or the like.

Generally, when measuring the impedance of the battery pack 22, it is necessary to measure in a low frequency band of about 0.1 Hz to 10 kHz, and the delta-sigma A/D converter 5 is also required to have low noise in the same frequency band. When the delta-sigma A/D converter 5 includes an operational amplifier 11 configured with, for example, a MOSFET, the level of low-frequency noise due to flicker noise is high. If such an operational amplifier 11 is used as is in the delta-sigma A/D converter 5, the low-frequency noise may increase.

An example of a frequency noise spectrum distribution is shown in the upper diagram of FIG. 17A as a comparative example. When the signal band is about 0.1 to 10 kHz, if the chopping frequency is set to about 10 kHz, the flicker noise will be mapped into the signal band, and the noise reduction effect may be reduced. The charges stored in the operational amplifier 11 and the parasitic capacitances Ci and Co of the wiring generate noise, so that an error in the conversion characteristics of the delta-sigma A/D converter 5 is generated. If the integral nonlinearity error (INL) deteriorates, it becomes impossible to measure DC voltage properly, which is particularly anomaly in battery monitoring applications.

To solve this difficulty, for example, the sampling frequency of the delta-sigma A/D converter 5 may be set to a relatively high frequency of about 2 MHz. By setting the sampling frequency in this way, the chopping frequency can be set to about a half of that frequency, i.e., 1 MHz. In the above-described embodiment and this embodiment, the chopping switches 12, 14, and 15 of the delta-sigma A/D converter 5 perform chopping and switching, thereby periodically switching the positive and negative input terminals and the positive and negative output terminals of the operational amplifier 11. As a result, the flicker noise can be configured to shift the higher frequency side in accordance with the switched chopping frequencies. As a result, flicker noise on the low frequency side can be reduced. Therefore, the delta-sigma A/D converter 5 is suitable for the battery monitor device 20 that measures the impedance of the unit cells Ce1 to Cen.

### Fourth Embodiment

The fourth embodiment will be described with reference to FIGS. 18 to 20. In the fourth embodiment, various modifications of the reset method will be described. FIGS. 18 to 20 show a connection method of the switches Si, So, Sim, Sip, Sop, Som, Sfmp, and Sfpm configured around the first integrator 1. As shown in FIGS. 18 to 20, the switches Si, So, Sim, Sip, Sop, Som, Sfmp, and Sfpm may be connected to reset the differential input terminals.

In the example shown in FIG. 18, the switch Si is configured to set the differential input terminals of the operational amplifier 11 to the same potential at the timing of resetting, and the switch So is configured to set the differential output terminals to the same potential. In this case, for example, the differential input terminals of the operational amplifier 11 may be connected by a single switch Si so that the differential input terminals are at the same potential as each other, and the differential output terminals of the operational amplifier 11 may be connected by a single switch So so that the differential output terminals are at the same potential as each other. This also provides the same effects as the above-described embodiment.

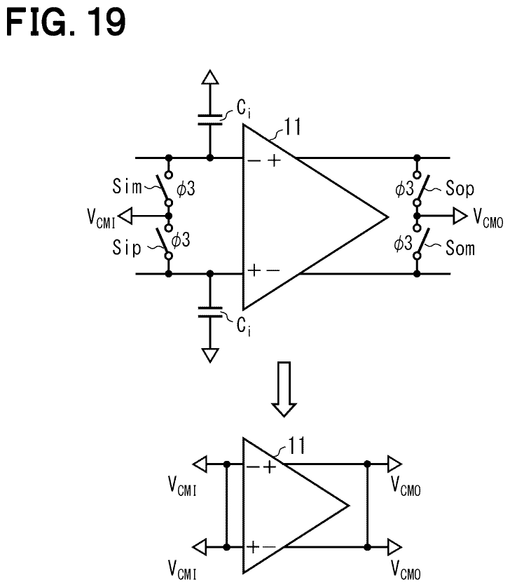

Also, as shown in FIG. 19, the switches Sim and Sip may be provided so that, at the timing of resetting, the positive input terminal and the negative input terminal of the operational amplifier 11 are each connected to an input common potential VCMI, which is a predetermined potential, so that the differential input terminals are at the same potential.

As shown in FIG. 19, the switches Som and Sop may be provided to connect the differential output terminals of an operational amplifier 11 to each other, so that the differential output terminals have the same potential. The switches Som and Sop may be provided so that the positive and negative output terminals of the operational amplifier 11 are connected to a reference potential VCMO, which is a predetermined potential, and the differential output terminals are at the same potential. This also provides the same effects as the above-described embodiment.

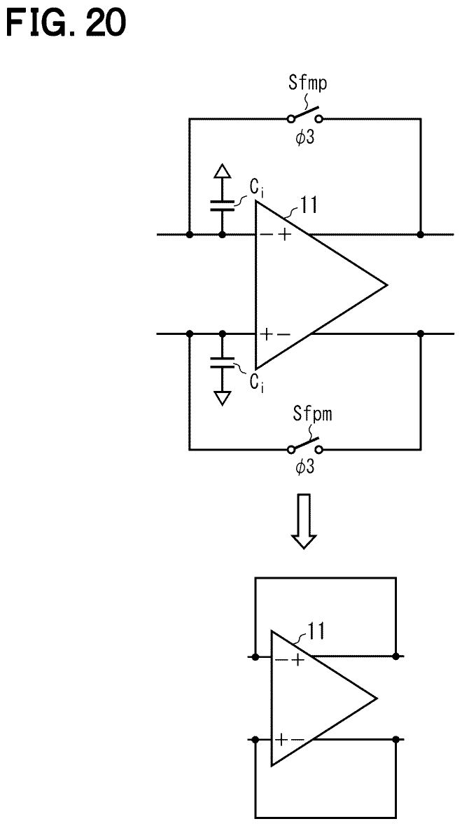

As shown in FIG. 20, the switches Sfmp and Sfpm may be configured to connect the positive input terminal and negative output terminal of the operational amplifier 11 and also to connect the negative input terminal and positive output terminal of the operational amplifier 11 when resetting. By configuring the switches Sfmp and Sfpm as shown in FIG. 20, the output of the operational amplifier 11 is fed back at the timing of resetting, so that the potential of the differential input terminals can be fixed to the potential of the output terminal of the operational amplifier 11, and as a result, the differential input terminals of the operational amplifier 11 can each be reset.

### OTHER EMBODIMENTS

The present disclosure is not limited to the embodiment described above, and, for example, may be modified or expanded, which will be described.

The delta-sigma A/D converter 5 may be applied to devices other than the battery monitor device 20 having the battery impedance measurement function.

Although the configuration in which the second integrator 2 is connected in the subsequent stage of the first integrator 1, has been described, the present embodiments can also be applied to a configuration in which a differential amplifier is connected instead of the second integrator 2, or to a configuration in which the output of the first integrator 1 is input directly to the quantizer 4. Therefore, the pseudo-addition circuit 3 and the second integrator 2 may be provided as needed.

In addition to the contents described in claims, the present embodiments also include the following features.

### (Feature 1)

A delta-sigma A/D converter uses a differential operational amplifier (11).

The delta-sigma A/D converter includes: a pair of feedback capacitors (Cf1) that have a differential configuration and feedback-connect between differential input terminals and differential output terminals of the operational amplifier; and a first integrator (1) functioning as a switched capacitor, and having a chopping switch (14) capable of switching polarity between the differential input terminals of the operational amplifier and the pair of feedback capacitors. The first integrator includes a switch (Sim, Sip, Si, Sfmp, Sfpm) that reset a potential of the differential input terminals of the operational amplifier when the feedback capacitor (Cf1) and the differential input terminals of the operational amplifier are disconnected by the chopping switch.

### (Feature 2)

The delta-sigma A/D converter according to feature 1 further includes: a second integrator (2) having a differential configuration and connected in a subsequent stage of the first integrator.

### (Feature 3)

In the delta-sigma A/D converter according to feature 1 or 2, the switches (Sim, Sip) are configured to set the differential input terminals of the operational amplifier to predetermined potentials (VCMI), respectively, when resetting the operational amplifier. The delta-sigma A/D converter further includes a switch (So) that sets the differential output terminals to a same potential when resetting the operational amplifier.

### (Feature 4)

In the delta-sigma A/D converter according to feature 1 or 2, the switch (Si) is configured to set the differential input terminals of the operational amplifier to a same potential when resetting the operational amplifier. The delta-sigma A/D converter further includes a switch (So) that sets the differential output terminals to a same potential when resetting the operational amplifier.

### (Feature 5)

In the delta-sigma A/D converter according to feature 1 or 2, the switch (Si) connects the differential input terminals of the operational amplifier when resetting the operational amplifier, so that the differential input terminals have a same potential.

### (Feature 6)

In the delta-sigma A/D converter according to any one of features 1 to 5, the differential input terminals include a positive input terminal and a negative input terminal. In the delta-sigma A/D converter according to any one of features 1 to 5, the switch (Sim, Sip) connects each of the positive input terminal and the negative input terminal of the operational amplifier to a predetermined potential when resetting the operational amplifier, so that the differential input terminals have a same potential.

### (Feature 7)

In the delta-sigma A/D converter according to any one of features 3 to 6, the switch (So) connects the differential output terminals together when resetting the operational amplifier, so that the differential output terminals have a same potential.

### (Feature 8)

In the delta-sigma A/D converter according to any one of features 3 to 6, the switches (Som, Sop) connect each of the differential output terminals of the operational amplifier to a predetermined potential when resetting the operational amplifier, so that the differential output terminals have a same potential.

### (Feature 9)

In the delta-sigma A/D converter according to any one of features 1 to 8, the differential input terminals include a positive input terminal and a negative input terminal, and the differential output terminals include a positive output terminal and a negative output terminal. The switch (Sfmp, Sfpm) connects the positive input terminal and the negative output terminal of the operational amplifier and connects the negative input terminal and the positive output terminal of the operational amplifier when resetting the operational amplifier.

### (Feature 10)

A battery monitor device includes the delta-sigma A/D converter (5) according to any one of features 1 to 9.

In the drawings, reference numeral 1 denotes a first integrator, reference numeral 2 denotes a second integrator, reference numeral 3 denotes a pseudo-adder circuit, reference numeral 4 denotes a quantizer, reference numeral 5 denotes a delta-sigma A/D converter, and reference numeral Cf1 denotes a feedback capacitor.

Although the present disclosure has been described in accordance with the foregoing embodiments, it is understood that the present disclosure is not limited to the above embodiments or structures. The present disclosure includes various modifications or deformations within an equivalent range. Furthermore, various combination and formation, and other combination and formation including one, more than one or less than one element may be made within the spirit and scope of the present disclosure.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A delta-sigma analog-to-digital converter using a differential operational amplifier, the delta-sigma A/D converter comprising:
a pair of feedback capacitors that have a differential configuration and feedback-connect between differential input terminals and differential output terminals of the operational amplifier; and
a first integrator functioning as a switched capacitor and having a chopping switch capable of switching polarity between the differential input terminals of the operational amplifier and the pair of feedback capacitors, wherein:
the first integrator includes a switch that reset potentials of the differential input terminals of the operational amplifier when the feedback capacitor and the differential input terminals of the operational amplifier are disconnected by the chopping switch.

2. The delta-sigma analog-to-digital converter according to claim 1, further comprising:
a second integrator having a differential configuration and connected in a subsequent stage of the first integrator.

3. The delta-sigma analog-to-digital converter according to claim 1, wherein:
the switch is configured to set the differential input terminals of the operational amplifier to predetermined potentials, respectively, when resetting the operational amplifier,
the delta-sigma analog-to-digital converter further comprising:
a switch that sets the differential output terminals to a same potential when resetting the operational amplifier.

4. The delta-sigma analog-to-digital converter according to claim 1, wherein:
the switch is configured to set the differential input terminals of the operational amplifier to a same potential when resetting the operational amplifier; and
the delta-sigma analog-to-digital converter further comprising:
a switch that sets the differential output terminals to a same potential when resetting the operational amplifier.

5. The delta-sigma analog-to-digital converter according to claim 1, wherein:
the switch connects the differential input terminals of the operational amplifier together when resetting the operational amplifier, so that the differential input terminals have a same potential.

6. The delta-sigma analog-to-digital converter according to claim 1, wherein:
the differential input terminals include a positive input terminal and a negative input terminal; and
the switch connects each of the positive input terminal and the negative input terminal of the operational amplifier to a predetermined potential when resetting the operational amplifier, so that the differential input terminals have a same potential.

7. The delta-sigma analog-to-digital converter according to claim 3, wherein:
the switch connects the differential output terminals together when resetting the operational amplifier, so that the differential output terminals have a same potential.

8. The delta-sigma analog-to-digital converter according to claim 3, wherein:
the switch connects each of the differential output terminals of the operational amplifier to a predetermined potential when resetting the operational amplifier, so that the differential output terminals have a same potential.

9. The delta-sigma analog-to-digital converter according to claim 1, wherein:
the differential input terminals include a positive input terminal and a negative input terminal, and the differential output terminals include a positive output terminal and a negative output terminal; and
the switch connects the positive input terminal and the negative output terminal of the operational amplifier and connects the negative input terminal and the positive output terminal of the operational amplifier when resetting the operational amplifier.

10. A battery monitor device comprising:
at least one delta-sigma analog-to-digital converter according to claim 1.

11. The battery monitor device according to claim 10, further comprising:
a battery monitor IC; and
an RC filter, wherein:
the battery monitor IC is configured using an integrated circuit, and measures an impedance of each of n pieces of unit cells that constitute a battery pack;
a series circuit of a limitation resistor, an N-channel MOSFET, and a shunt resistor is connected in parallel to the battery pack;
the limitation resistor controls an on and off operation of the MOSFET to limit a magnitude of an intermittent current that flows therethrough;
the at least one delta-sigma analog-to-digital converter includes a plurality of delta-sigma analog-to-digital converters;
the RC filter, which is a low-pass type filter including a resistor and a capacitor, is connected to each of the n pieces of unit cells that provide a secondary battery;
both ends of the capacitor that constitutes the RC filter are connected to the differential input terminals of one of the plurality of delta-sigma analog-to-digital converters;
both ends of the shunt resistor are connected to the differential input terminals of another one of the plurality of delta-sigma analog-to-digital converters via an the filter.

12. The battery monitor device according to claim 11, further comprising:
a plurality of decimation filters;
a plurality of multipliers; and
a plurality of low pass filters;
a sine and cosine generation unit;
a pulse width modulation and pulse density modulation (PWM/PDM) modulator;
an impedance calculation unit; and
a register, wherein:
one of the plurality of delta-sigma analog-to-digital converters, one of the plurality of decimation filters, one of the plurality of multipliers, and one of the plurality of low pass filters provide a set of the delta-sigma analog-to-digital converters, the decimation filters, the multipliers, and the low pass filters;
a numerical number of sets is equal to a numerical number of the n pieces of unit cells plus one for current measurement;
the impedance calculation unit includes a digital control circuit and a counter;
the register is connected to an interface for communicating with an external higher level device;
the register is written to by the external higher level device via the interface;
a frequency setting of the sine and cosine generation unit and a modulation method in the PWM/PDM modulator are set in the register;
when the register receives a measurement start command via the interface, the sine and cosine generation unit starts operating and the PWM/PDM modulator starts operating;
the PWM/PDM modulator outputs a pulse width modulation (PWM) signal or a pulse density modulation (PDM) signal based on the modulation method set in the register via the interface from the external higher-level device;
the PWM/PDM modulator is connected to a gate of the MOSFET so that the PWM signal or PDM signal is given to the MOSFET;
when the MOSFET is turned on, the delta-sigma analog-to-digital converter detects a terminal voltage corresponding to an excitation current flowing from the battery pack through the limitation resistor to the shunt resistor;
the delta-sigma analog-to-digital converter measures the terminal voltage of each of the n pieces of unit cells and the terminal voltage of the shunt resistor, and performs an analog-to-digital conversion;
an output data of the delta-sigma analog-to-digital converter is input to the decimation filter;
the decimation filter uses a cascaded integrator-comb (CIC) filter, which reduces a sampling frequency and converts the output data into a multi-bit digital value;
the multi-bit digital value of the decimation filter is branched into two pieces and input to the multiplier;
the multiplier receives sine and cosine signals generated by the sine/cosine generation unit and perform an orthogonal conversion;
an output of the multiplier is input to the low pass filter;
the low pass filter cuts off a high frequency to obtain DC data, and output real and imaginary parts of the DC data to the impedance calculation unit;
the impedance calculation unit receives the real and imaginary parts of the DC data, and outputs a calculation impedance of each of the n pieces of unit cells to the register; and
the calculation impedance of each of the n pieces of unit cells stored in the register is transmitted to the external higher-level device.
